(19) United States
(12) Patent Application Publication
(10) Pub. No.: US 2022/0071021 A1
(43) Pub. Date: Mar. 3, 2022

(54) PRINTED WIRING BOARD AND ELECTRONIC DEVICE

(71) Applicant: Mitsubishi Electric Corporation, Tokyo (JP)

(72) Inventors: Koji SHIGETA, Tokyo (JP); Masato MORITA, Tokyo (JP); Kazuo NAMIKOSHI, Tokyo (JP); Tomotaka KOJIMA, Tokyo (JP); Kanji UNNO, Tokyo (JP); Yuya HARADA, Tokyo (JP)

(21) Appl. No.: 17/419,760

(22) PCT Filed: Mar. 18, 2019
(86) PCT No.: PCT/JP2019/011272

§ 371 Date: Jun. 30, 2021

(51) Int. Cl. H05K 3/34; H05K 1/18; H05K 1/11

(52) U.S. Cl. CPC H05K 3/341; H05K 2203/042; H05K 1/111; H05K 1/181

(57) ABSTRACT

A printed wiring board includes a base material, a plurality of electrode pads to which an electronic component is soldered, the electrode pads being formed on a surface of the base material, a molten-solder introducing protrusion formed on the surface of the base material and connected to each of the electrode pads to draw molten solder into the electrode pad during soldering, and a molten-solder separating protrusion formed on the surface of the base material and connected to each of the electrode pads to help separation of molten solder from the electrode pad at a moment of separation of molten solder, wherein the molten-solder introducing protrusion, the electrode pad, and the molten-solder separating protrusion are aligned in line.

### FIELD

The present invention relates to a printed wiring board including an electrode pad to which an electrode of an electronic component is soldered, and also relates to an electronic device including the printed wiring board.

### BACKGROUND

As a method for soldering an electronic component to a printed wiring board, there is a jet soldering method in which a target object to be soldered is immersed in molten solder. In the jet soldering method, a solder-joint portion such as an electrode pad on the printed. wiring board or an electrode of an electronic component is applied with flux in advance, and thereafter heated to increase the temperature. This activates the flux, and then an coating is removed from the surface of the electrode, so that the solder-joint portion can be kept in a clean state. Thereafter, the printed wiring board and the electronic component are brought into contact with jet solder in a molten state. When the molten solder and the solder-joint portion sufficiently come into contact with each other, and the molten solder separates from the solder-joint portion in a stable manner, then a normal fillet is formed and thus the soldering is completed.

However, during the soldering, if the solder-joint portion and the molten solder do riot sufficiently come into contact with each other, a problem called “incomplete solder” occurs in which solder is not formed on the electrode pad. A the time of separation of molten solder from the solder-joint portion, a problem called “excessive solder” occurs in which the molten solder is excessively applied when the molten solder is drawn back to the electrode pad on the printed wiring board or to the electrode of the electronic component, and thus does not separate normally from the solder-joint portion.

Patent Literature 1 discloses a printed wiring board on which a solder reserving pad is provided connecting to one side of the last pad positioned at the trailing end of the printed wiring board in its conveyance direction in a jet soldering method, the one side facing toward the soldering direction. The printed wiring board disclosed in Patent Literature 1 can reduce the occurrence of excessive solder on the last pad during the jet soldering.

### CITATION LIST

### Patent Literature

Patent Literature 1: Japanese Patent Application Laid-open No. 2003-142810

### SUMMARY

### Technical Problem

The printed wiring board disclosed in Patent Literature 1 does not have a section to help introduce molten solder relative to the soldering direction. Thus, while the occurrence of excessive solder can be reduced, incomplete solder may possibly occur. Even though incomplete solder may riot occur, the amount of molten solder to be supplied tends to vary. As a result of this, the fillet shape at a solder-joint portion differs among electrode pads. There is thus a problem that when a temperature cycle occurs, such as a temperature change due to use or an electronic device having the printed wiring board incorporated therein, or a temperature change due to installation environment, then a thermal stress is concentrated only on a solder-joint portion with a smaller amount of solder, and this leads the solder-joint portion to earlier fatigue failure and impairs its long-term reliability.

The present invention has been achieved to solve the above problems, and an object of the present invention is to provide a printed wiring board on which variations in the amount of solder to be supplied to each of a plurality of electrode pads are reduced.

### Solution to Problem

To solve the above problems and achieve the object, a printed wiring board according to the present invention includes: a base material; and a plurality of electrode pads to which an electronic component is soldered, the electrode pads being formed on a surface of the base material. The printed wiring board according to the present invention includes: a molten-solder introducing protrusion formed on the surface of the base material and connected to each of the electrode pads to draw molten solder into the electrode pad during soldering; and a molten-solder separating protrusion formed on the surface of the base material and connected to each of the electrode pads to help separation of molten solder from the electrode pads at a moment of separation of molten solder. The molten-solder introducing protrusion, the electrode pad, and the molten-solder separating protrusion are aligned in line.

### Advantageous Effects of Invention

The printed wiring board according to the present invention has an effect of being possible to reduce variations in the amount of solder to be supplied to each of a plurality of electrode pads.

### BRIEF DESCRIPTION OF DRAWINGS

FIG. 1 is a top view of a printed wiring board according to a first embodiment of the present invention.

FIG. 2 is a top view of the printed wiring board according to the first embodiment with a chip-form electronic component installed thereon.

FIG. 3 is a side view of the printed wiring board according to the first embodiment in a state in which an electronic component is being soldered to the printed wiring board.

FIG. 4 is a diagram illustrating a first modification of the printed wiring board according to the first embodiment.

FIG. 5 is a diagram illustrating a second modification of the printed wiring board according to the first embodiment.

FIG. 6 is a diagram illustrating a third modification of the printed wiring board according to the first embodiment.

FIG. 7 is a diagram illustrating a fourth modification of the printed wiring board according to the first embodiment.

FIG. 8 is a diagram illustrating a configuration of an electronic device using the printed wiring board according to the first embodiment.

### DESCRIPTION OF EMBODIMENTS

A printed wiring board and an electronic device according to embodiments of the present invention will be described in detail below with reference to the accompanying drawings. The present invention is not limited to the embodiments.

### FIRST EMBODIMENT

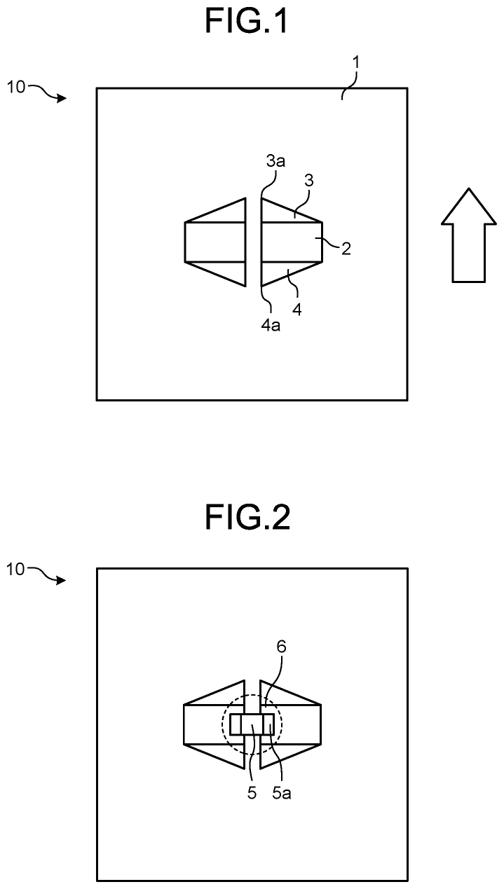

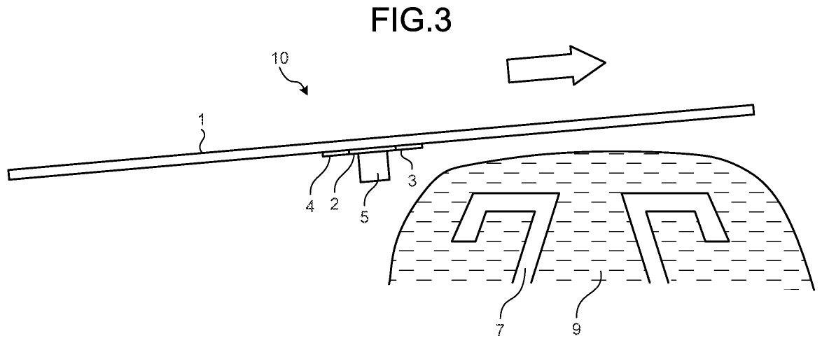

FIG. 1 is a top view of a printed wiring board according to a first embodiment of the present invention. FIG. 2 is a top view of the printed wiring board according to the first embodiment with a chip-form electronic component installed thereon. FIG, 3 is a side view of the printed wiring board according to the first embodiment in a state in which the electronic component is being soldered to the printed wiring board. On the surface of a printed wiring board 10, electrode pads 2 are provided to which. electrodes 5a of a chip-form electronic component 5 are joined by soldering. A base material 1 of the printed wiring board 10 is made of an insulating material. As the base material 1 of the printed wiring board 10, a base material of glass woven fabric, glass nonwoven fabric, or paper immersed with epoxy resin, polyimide resin, or phenolic resin can be exemplified. However, the base material 1 is not limited thereto. Further, on the leading side of the electrode pads 2 in a soldering direction, molten-solder introducing protrusions 3 are formed to draw molten solder 9 in a let state into the electrode pads 2.

The soldering direction refers to a direction of conveying the printed wiring board 10 when jet soldering is performed. The soldering direction is illustrated by the arrow in FIG. 1. In contrast, on the trailing side of the electrode pads 2 in the soldering direction, molten-solder separating protrusions 4 are formed to be designed to help separation of the molten solder 9 from the electrode pads 2. As the material of the molten solder 9, it is possible to use solder alloy (Sn—3Ag−0.5Cu) that contains silver whose mass percentage as 3%, copper whose mass percentage as 0.5%, and the remaining mass percentage of tin along with unavoidable impurities. However, the material of the molten solder 9 is not limited thereto. It is allowable to use any of Sn—Cu-based solder, Sb—Bi-based solder, Sb—In-based solder, Sn—Sb-based solder, or Sn—Pb-based solder as the material of the molten solder 9.

On a pair of electrode pads 2 to which both. electrodes of the chip-form electronic component 5 are joined, tip end sections 3a of the molten-solder introducing protrusions 3 are located to have a shortest distance from each other. On the pair of electrode pads 2 to which both the electrodes of the chip-form electronic component 5 are joined, tip end sections 4a of the molten-solder separating protrusions 4 are located to have a shortest distance from each other.

A board applied with flux in advance is conveyed in the soldering direction by a jet soldering device 7 to perform soldering by bringing a solder-joint portion into contact with the molten solder 9 in a jet state. In a jet soldering method, a solder-joint portion such as the electrode pads 2 on the printed wiring board 10 and the electrodes 5a of the electronic component 5 is immersed in the molten solder 9. In this jet soldering method, a molten-solder non-contact region 6 is present around the electronic component 5 that is a target to be soldered due to: a gas component of volatilized flux; air bubbles engulfed at the time of contacting let solder; a portion of the electronic component 5 other than the electrodes 5a, which is not joined with solder; and other factors. The presence of the molten-solder non-contact region 6 is a cause of incomplete solder. That is, the molten-solder non-contact region 6 is present around the electronic component 5, which is a cause of the occurrence of insufficient application of the molten solder 9 to the electrode pads 2 on the printed wiring board 10.

On the leading side of the printed wiring board 10 according to the first embodiment in the soldering direction, the molten-solder introducing protrusions 3 are provided to draw the molten solder 9 into the electrode pads 2. The tip end sections 3a of the molten-solder introducing protrusions 3 extend to outside of the molten-solder non-contact region 6. In addition, the electrode pad 2 and the molten-solder introducing protrusion 3 are formed from the same conductor. Due to this structure, when the molten solder 9 comes into contact with the printed wiring board 10 during let soldering, the molten solder 9 that is in contact with. the molten-solder introducing protrusions 3 can be drawn into the electrode pads 2 and the electrodes 5a of the electronic component 5. Thus, the printed wiring board. 10 according to the first embodiment can prevent incomplete solder.

On the trailing side of the printed wiring board 10 in the soldering direction, the molten-solder separating protrusions 4 are provided to be designed to help separation of the molten solder 9. The tip end sections 4a of the molten-solder separating protrusions 4 extend to outside of the molten-solder non-contact region 6 in addition, the electrode pad 2 and the molten-solder separating protrusion 4 are formed from the same conductor. At the time of separation of the molten solder 9 during let soldering, the molten solder 9 separates from the tip end sections 4a of the molten-solder separating protrusions 4. Thus, the molten solder 9 is not drawn back to the electrode pads 2 on the printed wiring board 10 or the electrodes 5a of the electronic component 5. Therefore, on the printed wiring board 10, the molten solder 9 can separate from any of the electrode pads 2 in a stable manner, and consequently an equal amount of the molten solder 9 is supplied to the electrode pads 2. Due to this configuration, the printed wiring board 10 can prevent excessive solder.

The printed wiring board 10 according to the first embodiment is provided with the molten-solder introducing protrusions 3 and the molten-solder separating protrusions 4, so that an equal amount of the molten solder 9 can be supplied to each of the electrode pads 2 and thus the fillet shape can be stabilized. Therefore, even when a temperature cycle has occurred in an electronic device having the printed wiring board 10 incorporated therein, the printed wiring board 10 can still obtain an effect of ensuring long-term reliability of the solder-joint portion.

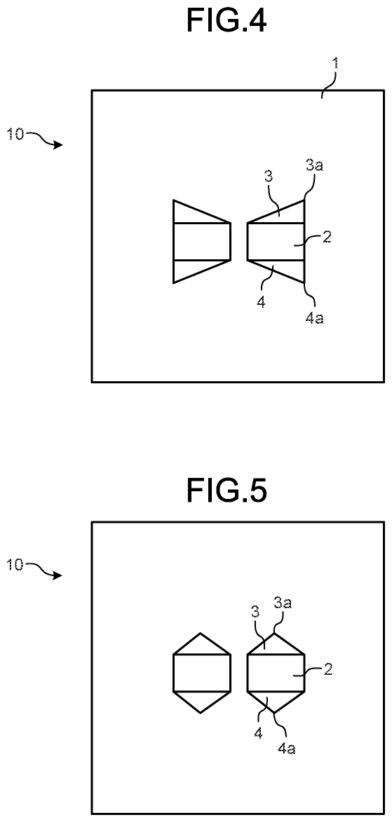

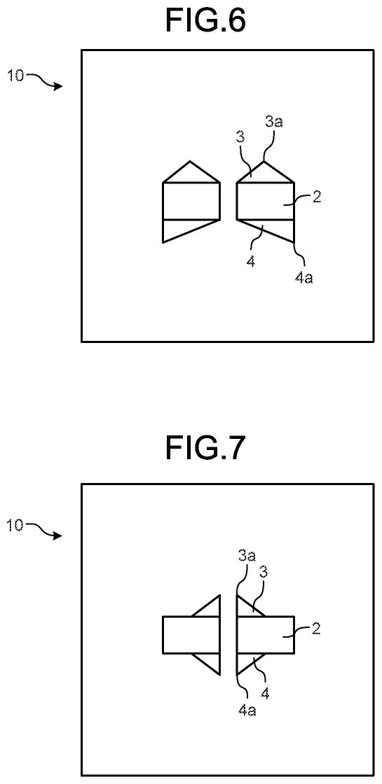

In the above descriptions, on the pair of electrode pads 2 to which both the electrodes of the chip-form electronic component 5 are joined, the tip end sections 3a of the molten-solder introducing protrusions 3 are located to have a shortest distance from each other, and the tip end sections 4a of the molten-solder separating protrusions 4 are located to have a shortest distance from each other. However, it is allowable to change the positions of the tip end sections 3a and the tip end sections 4a. FIG. 4 is a diagram illustrating a first modification of the printed wiring board according to the first embodiment. On the printed wiring board 10 according so the first modification of the first embodiment, the sip end sections 3a and 4a are located respectively at the outermost edge of two of the four sides of- the electrode pad 2, which are perpendicular to the soldering direction. FIG. 5 is a diagram illustrating a second modification of the printed wiring board according to the first embodiment. On the printed wiring board 10 according to the second modification of the first embodiment, the tip end sections 3a and 4a are located respectively at the central portion of two of the four sides of the electrode pad 2, which are perpendicular to the soldering direction. FIG. 6 is a diagram illustrating a third modification of the printed wiring board according to the first embodiment. On the printed wiring board 10 according to the third modification of the first embodiment, the tip end section 3a is located at the central portion of one of the two sides perpendicular to the soldering direction among the four sides of the electrode pad 2, and the tip end section 4a is located at the outermost edge of the other of the two sides. FIG. 7 is a diagram illustrating a fourth modification of the printed wiring board according to the first embodiment. On the printed wiring board 10 according to the fourth modification of the first embodiment, the molten-solder introducing protrusion 3 and the molten-solder separating protrusion 4 are located respectively on two of the four sides of the electrode pad 2, which are perpendicular to the soldering direction, between the central portion and the innermost edge of the two sides.

When the conditions described below are satisfied the molten solder can be introduced into and separated from the electrode pads 2, no matter where the molten-solder introducing protrusion 3 and the molten-solder separating protrusion 4 are provided on the electrode pad 2. The conditions include: the molten-solder introducing protrusion 3 and the molten-solder separating protrusion 4 are formed from the same conductor as the electrode pad 2; the tip end section 3a of the molten-solder introducing protrusion 3 and the tip end section 4a of the molten-solder separating protrusion 4 extend to outside of the molten-solder non-contact region 6; and the molten-solder introducing protrusion 3, the electrode pad 2, and the molten-solder separating protrusion 4 are aligned in line in the soldering direction. That is, the molten solder 9 can be introduced into and separated from the electrode pads 2 as long as the molten-solder introducing protrusion 3 is formed. on one side of the electrode pad 2 and the molten-solder separating protrusion 4 is formed on the other side thereof with the electrode pad 2 sandwiched therebetween.

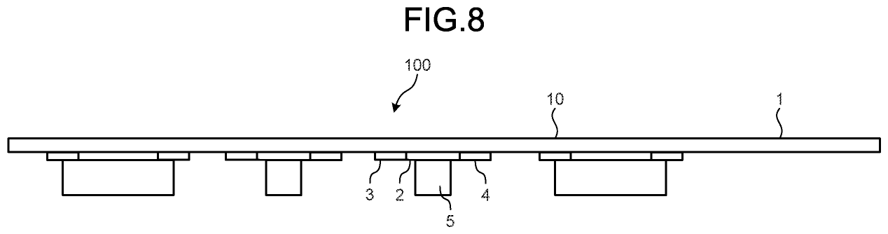

FIG. 8 is a diagram illustrating the configuration of an electronic device using the printed wiring board according to the first embodiment. An electronic device 100 can be configured by the printed wiring board 10 on which a plurality of electronic components 5 are implemented to form an electronic circuit that serves as a printed board.

The configurations described in the above embodiments are only examples of the content of the present. invention. The configurations can be combined with other well-known techniques, and part of each of the configurations can be omitted or modified without departing from the scope of the present invention,

### REFERENCE SIGNS LIST

1 base material, 2 electrode pad, 3 molten-solder introducing protrusion, 3a, 4a tip end section, 4 molten-solder separating protrusion, 5 electronic component, 5a electrode, 6 molten-solder non-contact region, 7 jet soldering device, 9 molten solder, 10 printed wiring board, 100 electronic device.

1. A printed wiring board comprising:
a base material;
a plurality of electrode pads to which an electronic component is soldered, the electrode pads being formed on a surface of the base material;
a molten-solder introducing protrusion formed on the surface of the base material and connected to each of the electrode pads to draw molten solder into the electrode pad during soldering; and
a molten-solder separating protrusion formed on the surface of the base material and connected to each of the electrode pads to help separation of molten solder from each of the electrode pads at a moment of separation of molten solder, wherein
the molten-solder introducing protrusion, the electrode pad, and the molten-solder separating protrusion are aligned in line.

2. The printed wiring board according to claim 1, wherein the molten-solder introducing protrusion and the molten-solder separating protrusion have a triangle shape in which one side connected to the electrode pad is a base.

3. An electronic device comprising:
the printed wiring board according to claim 1; and
an electronic component implemented on the printed wiring board.

4. An electronic device comprising:
the printed wiring board according to claim 2; and
an electronic component implemented on the printed wiring board.
